(19) United States
(12) Patent Application Publication
(10) Pub. No.: US 2010/0065114 A1
(43) Pub. Date: Mar. 18, 2010

(54) Dye-sensitized solar cell structure and method for fabricating the same

(76) Inventors: Eric Wei-Guang Diau, Zhubei City (TW); Chien-Chon Chen, Zhubei City (TW); Hsien-Wen Chung, Zhubei City (TW); Chin-Hsing Chen, Zhubei City (TW); Chi-Jui Sung, Zhubei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/232,478

(22) Filed: Sep. 18, 2008

(51) Int. Cl. H01L 31/00; B05D 5/12

(52) U.S. Cl. 136/256; 427/74

(57) ABSTRACT

The present invention discloses a dye-sensitized solar cell structure and a method for fabricating the same. The method of the present invention comprises forming insulation layers on a titanium plate; forming a plurality of titanium dioxide units on the titanium plate each containing a plurality of titanium dioxide nanotubes, wherein each insulation layer is arranged in between two adjacent titanium dioxide units; making the titanium dioxide units absorb a photosensitive dye; forming a transparent conductive film over the insulation layers and the titanium dioxide units; and filling an electrolyte into spaces each enclosed by the transparent conductive film, the titanium dioxide unit, the insulation layers. The present invention not only increases the electron transmission efficiency and photoelectric conversion efficiency but also promote the uniformity of the semiconductor layer.

### BACKGROUND OF THE INVENTION

1. Field of the Invention

The present invention relates to a solar cell structure and a method for fabricating the same, particularly to a dye-sensitized solar cell structure and a method for fabricating the same.

2. Description of the Related Art

The petroleum reserve can only continue to supply the world for about 20-30 years, and the coal reserve can only continue to supply the world for less than 100 years. Unfortunately, the demand for energy is growing at an unparalleled speed. Therefore, the energy crisis is urgent and needs confronting seriously. The traditional energy system depends on fossil fuels, such as petroleum, coal, natural gas, etc. However, fossil fuels pollute the living environment of human being. Solar energy is exactly the best solution to the energy crisis and environmental pollution.

Recently, many researches focus on how to reduce the cost of solar energy, including those of using experiences, numerical analyses, and theoretical predictions to promote the efficiency of solar cells. All the efforts of scientists and engineers are to reduce the cost and promote the efficiency of solar cells and then popularize solar energy. At present, solar cells are categorized into two groups: the semiconductor solar cells and the electrolyte solar cells. The semiconductor solar cells dominate the market now, including amorphous silicon solar cells, polycrystalline silicon solar cells, and monocrystalline solar cells. Among them, the monocrystalline solar cells have the highest photoelectric conversion efficiency of as high as over 20% and have superior stability. However, the monocrystalline solar cells have too high a price to be popularized. Now, considerable attention is paid to a novel dye-sensitized solar cell, which was developed with the nanometric semiconductor technology to simplify the fabrication process and reduce the fabrication cost.

A dye-sensitized solar cell comprises an anode, a cathode and an electrolyte, wherein a semiconductor layer is formed on the anode and absorbs a photosensitive dye. A dye-sensitized solar cell has the following reactions:
(1) After receiving incident light, the electrons of the photosensitive dye are excited from a ground state to an excited state.
(2) Electrons are transferred from the excited-state level of the photosensitive dye molecules to the conduction band of the semiconductor layer; at the same time, the electrolyte is oxidized, and the photosensitive dye is reduced; the result is equivalent to that holes are transferred from the photosensitive dye molecules to the electrolyte.
(3) Electrons are transferred from the semiconductor layer through a conductive layer to an external circuit and do work on an external load.
(4) Electrons come from the external circuit through the cathode back to the electrolyte and reduce the electrolyte.

The conventional dye-sensitized solar cell adopts titanium dioxide particles as the semiconductor layer. The fabrication process thereof includes preparing titanium dioxide particles and coating/depositing the titanium dioxide particles on a substrate. However, such a process is too complicated and too time-consuming. Besides, the process needs many chemicals and organic solvents. Further, the sizes of the titanium dioxide particles lack uniformity, and the film made thereof thus has insufficient flatness. Therefore, the process only applies to a smaller-area substrate.

Moreover, the photosensitive dye is absorbed by the gaps between titanium dioxide particles, and electrons have to pass through the crooked paths among particles before reaching an external circuit. Thus, the electron transmission efficiency is decreased.

To overcome the abovementioned problems, the present invention proposes a dye-sensitized solar cell structure and a method for fabricating the same, which can increase the uniformity of the semiconductor layer, raise the electron transmission efficiency, and promote the photoelectric conversion efficiency.

### SUMMARY OF THE INVENTION

The primary objective of the present invention is to provide a dye-sensitized solar cell structure and a method for fabricating the same, which can improve the electron transmission efficiency and promote the photoelectric conversion efficiency.

Another objective of the present invention is to provide a dye-sensitized solar cell structure and a method for fabricating the same, wherein the semiconductor layers has a higher uniformity.

To achieve the abovementioned objectives, the present invention proposes a dye-sensitized solar cell structure, which comprises a titanium plate; a plurality of titanium dioxide units each formed of a plurality of titanium dioxide nanotubes and absorbing a photosensitive dye; insulation layers each formed on the titanium plate and in between two adjacent titanium dioxide units; a transparent conductive film formed over the titanium dioxide units and the insulation layers; and an electrolyte filled into spaces each enclosed by the transparent conductive film, the titanium dioxide unit and the insulation layers.

The present invention proposes a method for fabricating a dye-sensitized solar cell structure comprising steps: preparing insulation layers on a titanium plate; forming on the surface of the titanium plate a plurality of titanium dioxide units each formed of a plurality of titanium dioxide nanotubes, wherein each insulation layer is positioned in between two adjacent titanium dioxide units; making the titanium dioxide units absorb a photosensitive dye; forming a transparent conductive film over the titanium dioxide units and the insulation layers; and filling an electrolyte into spaces each enclosed by the transparent conductive film, the titanium dioxide unit and the insulation layers.

Below, the embodiments are described in detail in cooperation with the drawings to make easily understood the technical contents, characteristics and accomplishments of the present invention.

### BRIEF DESCRIPTION OF THE DRAWINGS

FIG. 1 is a sectional view schematically showing a dye-sensitized solar cell structure according to a first embodiment of the present invention;

FIG. 2 is a diagram schematically showing the distribution of titanium dioxide nanotubes on a titanium plate according to the first embodiment of the present invention;

FIG. 3(a) is a perspective view schematically showing the dye-sensitized solar cell structure according to the first embodiment of the present invention;

FIG. 3(b) a diagram schematically showing the distribution of insulation layers and titanium dioxide units on a titanium plate according to the first embodiment of the present invention;

FIGS. 4(a)-4(e) are diagrams schematically showing the steps of a method for fabricating the dye-sensitized solar cell structure of the first embodiment of the present invention;

FIG. 5 is a sectional view schematically showing a dye-sensitized solar cell structure according to a second embodiment of the present invention;

FIGS. 6(a)-6(f) are diagrams schematically showing the steps of a method for fabricating the dye-sensitized solar cell structure of the second embodiment of the present invention;

FIG. 7 is a diagram showing the I-V relationships of the dye-sensitized solar cell structures according to the present invention; and

FIG. 8 is a diagram showing the relationship between the absorption ratio and the sunlight wavelength of the dye-sensitized solar cell structures according to the present invention.

### DETAILED DESCRIPTION OF THE INVENTION

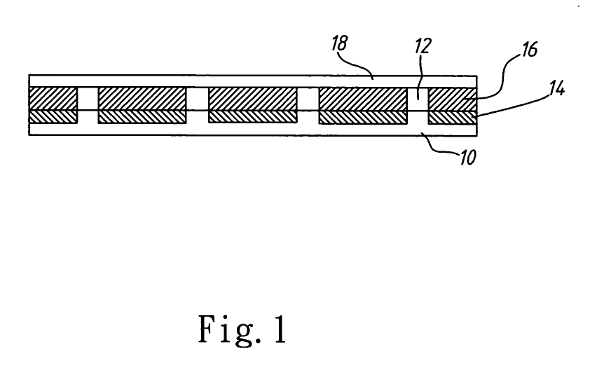

Refer to FIG. 1 a diagram schematically showing a dye-sensitized solar cell structure according to a first embodiment of the present invention. The present invention proposes a dye-sensitized solar cell structure, which comprises a titanium plate 10, insulation layers 12, a plurality of titanium dioxide units 14, a transparent conductive film 18, and an electrolyte 16. The titanium plate 10 is made of a flexible material, such as a pure titanium plate or a titanium alloy plate. For example, the titanium plate 10 may be a titanium-aluminum alloy plate. The titanium dioxide units 14 are formed on the surface of the titanium plate 10 and function as semiconductor layers. Each titanium dioxide unit 14 is formed of a plurality of titanium dioxide nanotubes. The gaps and cavities of each dioxide unit 14 absorb a photosensitive dye, including the gaps between the nanotubes and the cavities of the hollow nanotubes. The insulation layers 12 are formed on the titanium plate 10, and each insulation layer 12 is arranged in between two adjacent titanium dioxide units 14. The insulation layers 12 are made of a silicone resin, a plastic, a rubber, a polymer material or a non-conductive ceramic material. The transparent conductive film 18 is formed over the titanium dioxide units 14 and the insulation layers 12. The transparent conductive film 18 is made of ATO (Antimony Tin Oxide), FTO (Fluorine Tin Oxide), or ITO (Indium Tin Oxide). The insulation layers 12 are used to separate the titanium plate 10 from the transparent conductive film 18 lest short-circuit occur therebetween, wherefore the photoelectric conversion efficiency is promoted. The electrolyte 16 is filled into spaces each enclosed by the transparent conductive film 18, the titanium dioxide unit 14 and the insulation layers 12. The electrolyte 16 may be an iodine ion solution, a gel containing iodine ions, or TBP (tributyl phosphate). The iodine ions of the electrolyte 16 can be oxidized or reduced to release or absorb electrons.

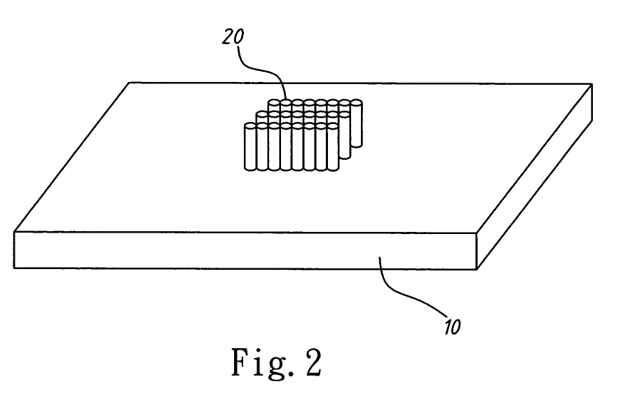

Refer to FIG. 2. Each titanium dioxide unit 14 is formed of a plurality of titanium dioxide nanotubes 20. The titanium dioxide nanotubes 20 are arranged orderly and have a uniform diameter. Therefore, the path to transmit electrons to the titanium plate 10 becomes shorter, and the electron transmission efficiency in the titanium dioxide units 14 increases. Thus, the present invention can apply to a large-area substrate.

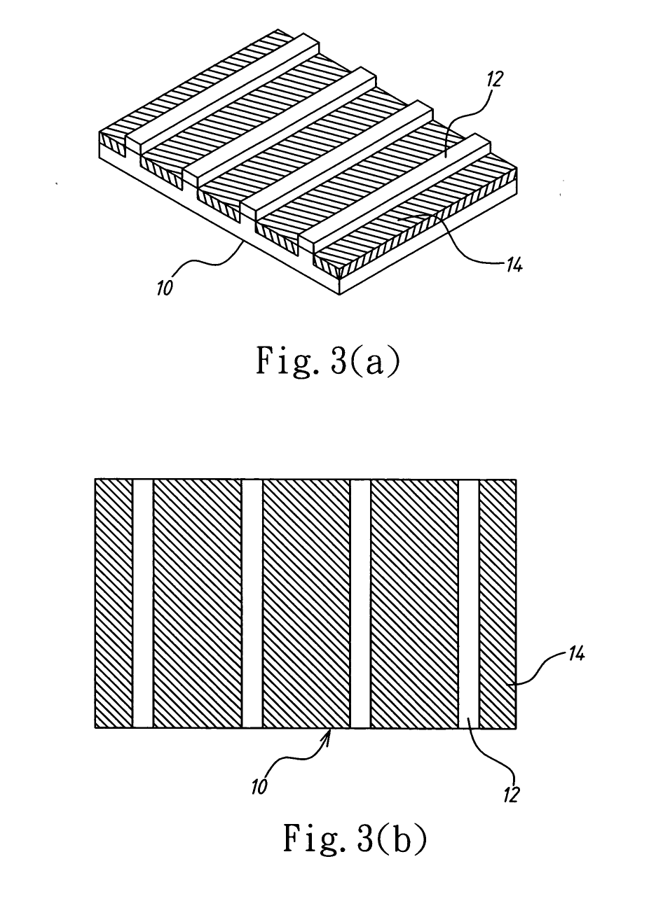

Refer to FIG. 3(a) and FIG. 3(b). As shown in FIG. 3(a), the insulation layers 12 are in form of a plurality of separating strips. FIG. 3(b) shows the distribution of the insulation layers 12 and the titanium dioxide units 14 on the titanium plate 10.

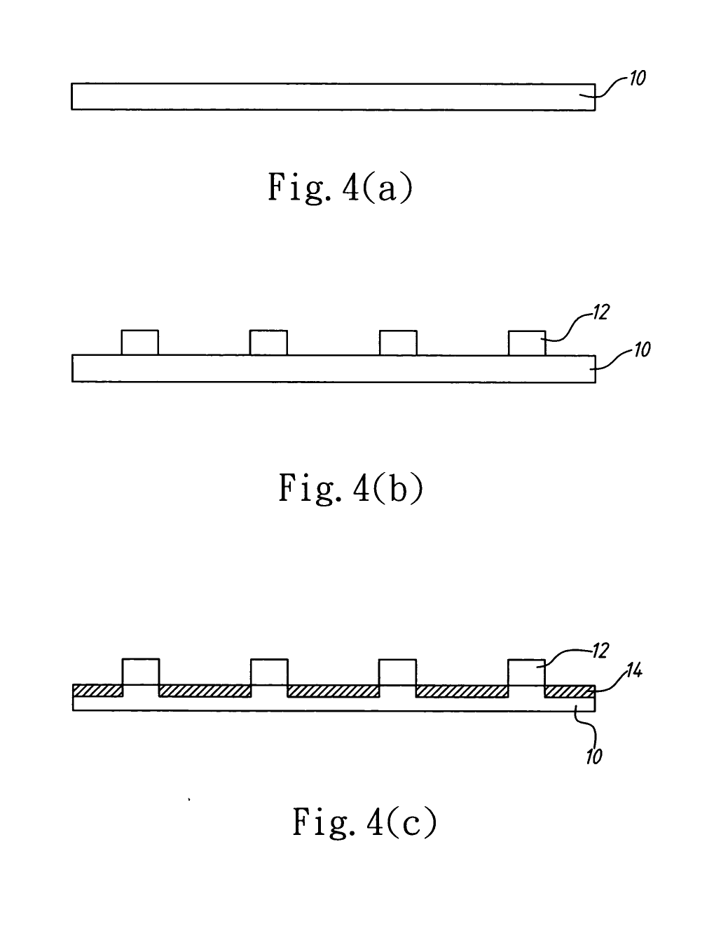

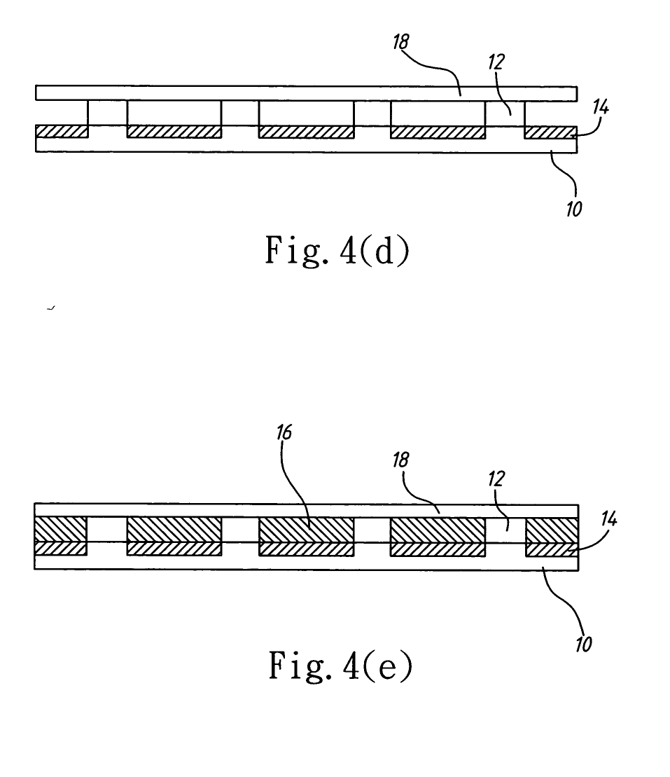

Refer to from FIG. 4(a) to FIG. 4(e) for a method for fabricating the dye-sensitized solar cell structure of the first embodiment of the present invention. As shown in FIG. 4(a), a titanium plate 10 is provided firstly. Next, as shown in FIG. 4(b), insulation layers 12 are formed on the titanium plate 10. Next, as shown in FIG. 4(c), an anodizing treatment is used to form a plurality of titanium dioxide units 14 on the titanium plate 10. For example, the titanium plate 10 is immersed in the ethylene-glycol solution of 0.5% ammonium fluoride, and a 60 V bias is applied thereto at an ambient temperature for 8-12 hours. Each titanium dioxide unit 14 is formed of a plurality of titanium dioxide nanotubes, and each insulation layer 12 is arranged in between two adjacent titanium dioxide units 14. Next, a heat treatment is performed on the titanium plate 10 to convert the titanium dioxide nanotubes from a non-crystalline structure to an anatase phase crystalline structure. For example, the titanium plate 10 is placed in an oven and baked at 450° C. for 3 hours. Next, let the gaps and cavities of the titanium dioxide units 14 absorb a photosensitive dye. For example, the titanium plate 10 is immersed in a 0.3×10⁻³ M solution of an organic ruthenium at an ambient temperature for 6 hours. Alternatively, the titanium dioxide units 14 directly absorb a photosensitive dye without any heat treatment. Next, as shown in FIG. 4(d), a transparent conductive film 18 is formed over the titanium dioxide units 14 and the insulation layers 12. As the altitude of the insulation layers 12 is higher than that of the titanium dioxide units 14, spaces are formed thereamong, and each space is enclosed by the transparent conductive film 18, the titanium dioxide unit 14 and the insulation layers 12. Next, as shown in FIG. 4(e), an electrolyte 16 is filled into the spaces each enclosed by the transparent conductive film 18, the titanium dioxide unit 14 and the insulation layers 12.

In FIG. 4(c), a titanium dioxide film, i.e. the titanium dioxide units 14, is directly grown on the titanium plate 10 with an anodizing method. Compared with the conventional method of fabricating titanium dioxide particles and coating/depositing the particles into a film, the anodizing method is simpler and more time-efficient and has a better adhesion between the titanium dioxide film and the titanium plate 10. The anodizing method uses an electrolyte containing a fluoride, ADP (Ammonium Dihydrogen Phosphate), ammonium sulfate, and oxalic acid/an acidic solution. The fluoride may be hydrofluoric acid, sodium fluoride, potassium fluoride, ammonium fluoride, or a combination thereof. The acidic solution may be sulfuric acid, phosphoric acid, or nitric acid.

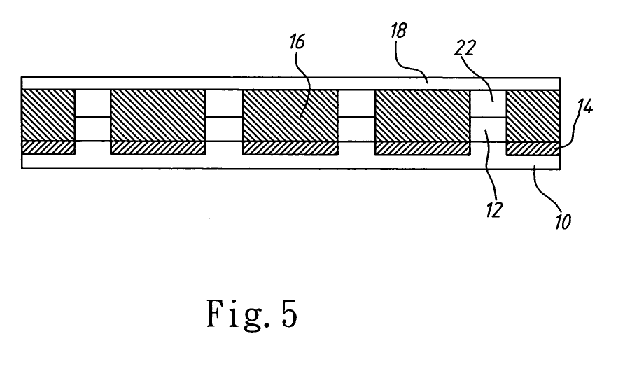

Refer to FIG. 1 and FIG. 5. FIG. 5 is a diagram schematically showing a dye-sensitized solar cell structure according to a second embodiment of the present invention. The second embodiment is different from the first embodiment in that metal layers 22 are arranged in between the insulation layers 12 and the transparent conductive film 18 and that the electrolyte 16 is filled into the spaces each enclosed by the transparent conductive film 18, the titanium dioxide unit 14, the metal layers 22 and the insulation layers 12. The metal layers 22 can reduce the leakage current and promote the photoelectric conversion efficiency.

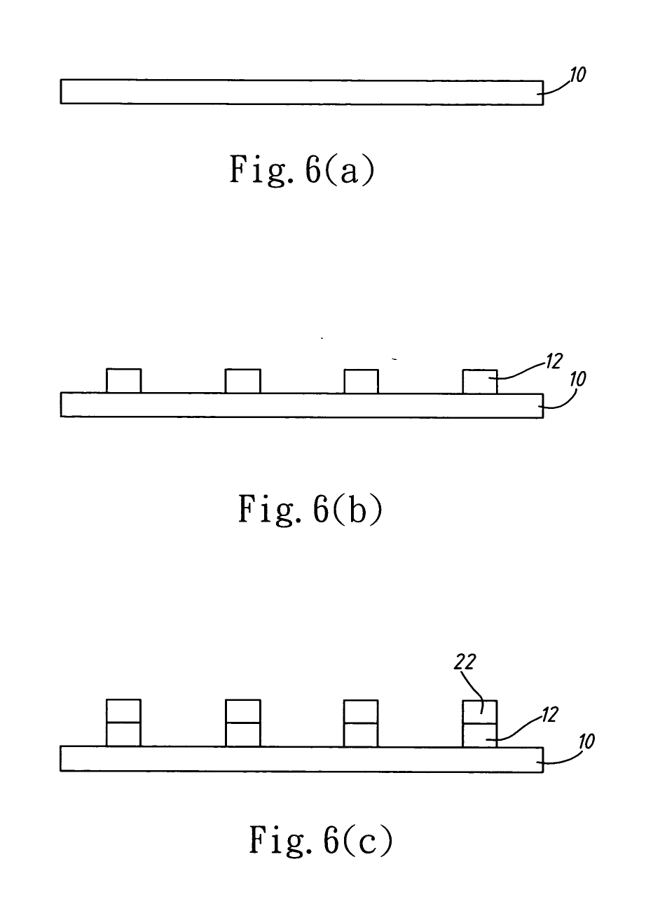

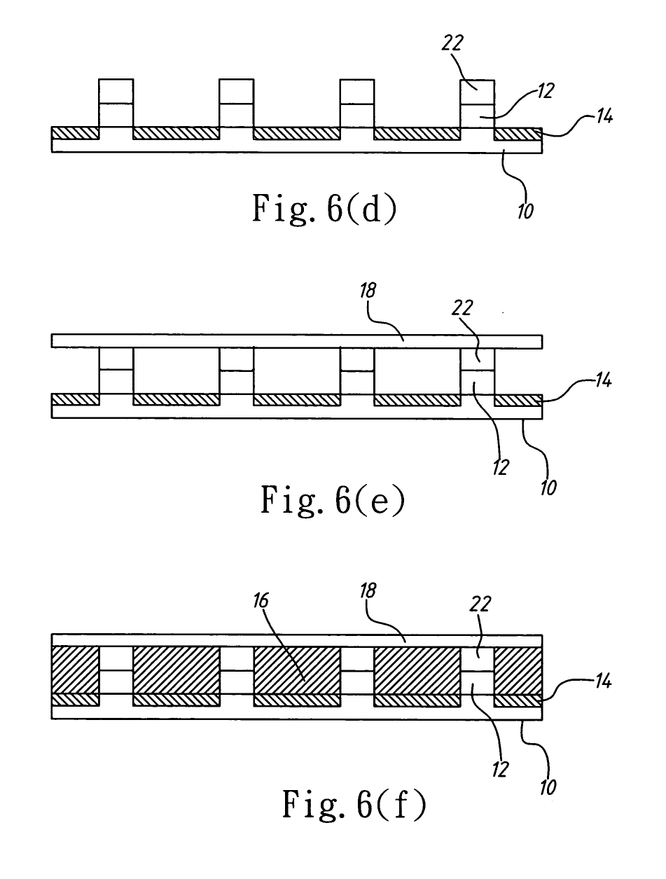

Refer to from FIG. 6(a) to FIG. 6(f) for a method for fabricating the dye-sensitized solar cell structure of the second embodiment of the present invention. The steps shown in FIG. 6(a) and FIG. 6(b) are identical to the steps shown in FIG. 4(a) and FIG. 4(b) and will not repeat herein. After the step of FIG. 6(b) is completed, the process proceeds to the step shown in FIG. 6(c), and metal layers 22 are formed on the insulation layers 12. Next, as shown in FIG. 6(d), an anodizing treatment is used to form a plurality of titanium dioxide units 14 on the titanium plate 10. For example, the titanium plate 10 is immersed in the ethylene-glycol solution of 0.5% ammonium fluoride, and a 60 V bias is applied thereto at an ambient temperature for 8-12 hours. Each titanium dioxide unit 14 is formed of a plurality of titanium dioxide nanotubes, and each insulation layer 12 is arranged in between two adjacent titanium dioxide units 14. Next, a heat treatment is performed on the titanium plate 10 to convert the titanium dioxide nanotubes from a non-crystalline structure to an anatase phase crystalline structure. For example, the titanium plate 10 is placed in an oven and baked at 450° C. for 3 hours. Next, let the gaps and cavities of the titanium dioxide units 14 absorb a photosensitive dye. For example, the titanium plate 10 is immersed in a 0.3×10⁻³ M solution of an organic ruthenium at an ambient temperature for 6 hours. Alternatively, the titanium dioxide units 14 directly absorb a photosensitive dye without any heat treatment. Next, as shown in FIG. 6(e), a transparent conductive film 18 is formed over the titanium dioxide units 14 and the metal layers 22. As the altitude of the metal layers 22 is higher than that of the titanium dioxide units 14, spaces are formed thereamong, and each space is enclosed by the transparent conductive film 18, the titanium dioxide unit 14, the metal layers 22 and the insulation layers 12. Next, as shown in FIG. 6(f), an electrolyte 16 is filled into the spaces each enclosed by the transparent conductive film 18, the titanium dioxide unit 14, the metal layers 22 and the insulation layers 12.

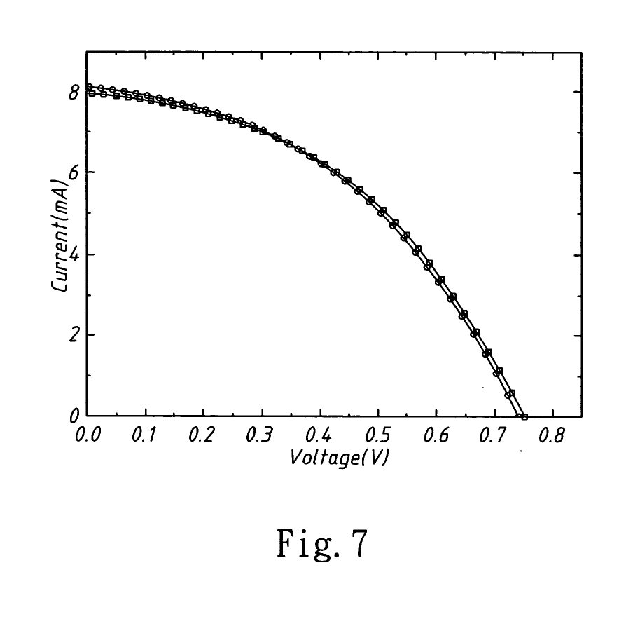

Refer to FIG. 7 a diagram showing the I-V relationships of the dye-sensitized solar cell structures according to the present invention, wherein the curve containing square dots represents the I-V relationship of the solar cell structure shown in FIG. 1, and the curve containing circle dots represents the I-V relationship of the solar cell structure shown in FIG. 5. The abovementioned curves are measured from sample areas of 4.5×1.6 cm². The solar cell structure shown in FIG. 1 features the following parameters: a short-circuit current density Jsc of 8.127 mA/cm², a short-circuit current Isc of 58.52 mA, an open-circuit voltage Voc of 0.734V, a filling factor FF of 0.43, and a photoelectric conversion efficiency of 2.59%. The solar cell structure shown in FIG. 5 features the following parameters: a short-circuit current density Jsc of 7.969 mA/cm², a short-circuit current Isc of 57.379 mA, an open-circuit voltage Voc of 0.749V, a filling factor FF of 0.44, and a photoelectric conversion efficiency of 2.63%. From the data, it is known that the metal layers can increase the photoelectric conversion efficiency.

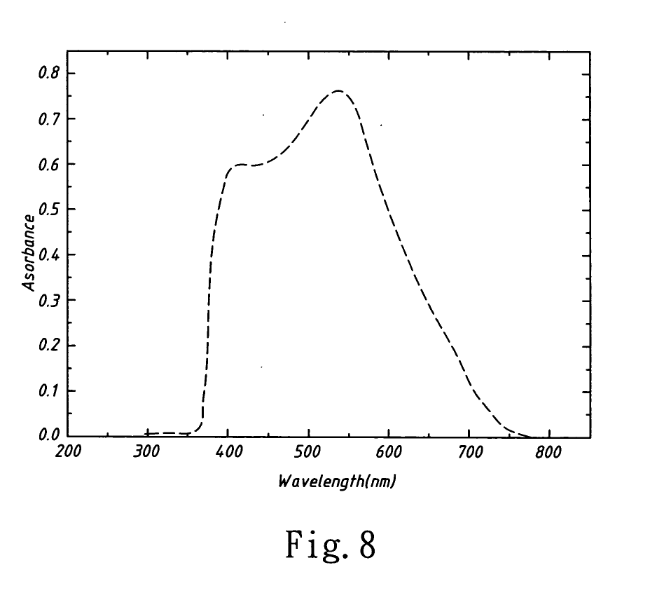

Refer to FIG. 8 a diagram showing the relationship between the absorption ratio and the sunlight wavelength. From the relationship, it is known that the sunlight with a wavelength of 550 nm has the highest absorption ratio—about 0.77.

In conclusion, the present invention not only increases the electron transmission efficiency and photoelectric conversion efficiency but also promote the uniformity of the semiconductor layer. Therefore, the present invention is a utility innovation.

The embodiments described above are only to exemplify the present invention but not to limit the scope of the present invention. Therefore, any equivalent modification or variation according to the shapes, structures, features, or spirit disclosed by the present invention is to be also included within the scope of the present invention.

What is claimed is:

1. A dye-sensitized solar cell structure comprising
a titanium plate;
a plurality of titanium dioxide units formed on said titanium plate, absorbing a photosensitive dye and each containing a plurality of titanium dioxide nanotubes;
insulation layers formed on said titanium plate and each arranged in between adjacent said titanium dioxide units;
a transparent conductive film formed over said titanium dioxide units and said insulation layers; and
an electrolyte filled into space each enclosed by said transparent conductive film, one of said titanium dioxide units and said insulation layers.

2. The dye-sensitized solar cell structure according to claim 1, wherein said insulation layers are in form of a plurality of separating strips.

3. The dye-sensitized solar cell structure according to claim 1, wherein metal layers are formed in between said transparent conductive film and said insulation layers, and said electrolyte is filled in to spaces each enclosed by said transparent conductive film, one of said titanium dioxide units, said metal layers and said insulation layers.

4. The dye-sensitized solar cell structure according to claim 1, wherein said titanium plate is made of a flexible material.

5. The dye-sensitized solar cell structure according to claim 1, wherein gaps and cavities of said titanium dioxide nanotubes absorb said photosensitive dye.

6. The dye-sensitized solar cell structure according to claim 1, wherein said insulation layers are made of a silicone resin, a plastic, a rubber, a polymer material or a non-conductive ceramic material.

7. The dye-sensitized solar cell structure according to claim 1, wherein said titanium dioxide units are fabricated with an anodizing method.

8. The dye-sensitized solar cell structure according to claim 1, wherein said titanium plate is made of a pure titanium plate or a titanium alloy plate.

9. The dye-sensitized solar cell structure according to claim 8, wherein said titanium alloy a titanium-aluminum alloy.

10. A method for fabricating a dye-sensitized solar cell structure comprising
Step (A): forming insulation layers on a titanium plate;
Step (B): forming a plurality of titanium dioxide units on said titanium plate, wherein each of said titanium dioxide units contains a plurality of titanium dioxide nanotubes, and each of said insulation layers is arranged in between adjacent said titanium dioxide units;
Step (C): making said titanium dioxide units absorb a photosensitive dye; and
Step (D): forming a transparent conductive film over said titanium dioxide units and said insulation layers; and filling an electrolyte into spaces each enclosed by said transparent conductive film, one of said titanium dioxide units and said insulation layers.

11. The method for fabricating a dye-sensitized solar cell structure according to claim 10 further comprising a step of forming metal layers in between said transparent conductive film and said insulation layers, wherein said electrolyte is filled into spaces each enclosed by said transparent conductive film, one of said titanium dioxide units, said metal layers and said insulation layers.

12. The method for fabricating a dye-sensitized solar cell structure according to claim 10, wherein after said Step (B), a heat treatment is performed on said titanium plate to convert said titanium dioxide nanotubes from a non-crystalline structure to an anatase phase crystalline structure; then said Step (C) succeeds.

13. The method for fabricating a dye-sensitized solar cell structure according to claim 10, wherein said insulation layers are in form of a plurality of separating strips.

14. The method for fabricating a dye-sensitized solar cell structure according to claim 10, wherein said insulation layers in form of a plurality of interlaced and netted areas.

15. The method for fabricating a dye-sensitized solar cell structure according to claim 10, wherein said titanium dioxide units are fabricated with an anodizing method.

16. The method for fabricating a dye-sensitized solar cell structure according to claim 10, wherein gaps and cavities of said titanium dioxide units absorb said photosensitive dye.
